(19) United States
(12) Patent Application Publication
(10) Pub. No.: US 2023/0240147 A1
(43) Pub. Date: Jul. 27, 2023

(54) POWER GENERATING ELEMENT, AND POWER GENERATING APPARATUS INCLUDING THE POWER GENERATING ELEMENT

(71) Applicant: CANON KABUSHIKI KAISHA, Tokyo (JP)

(72) Inventor: YUICHIRO MIYAUCHI, Tokyo (JP)

(21) Appl. No.: 18/152,074

(22) Filed: Jan. 9, 2023

(30) Foreign Application Priority Data
Jan. 26, 2022 (JP) 2022-010274

(51) Int. Cl. H10N 35/00; H02N 2/18

(52) U.S. Cl. CPC H10N 35/101; H02N 2/18

(57) ABSTRACT

A power generating element includes a magnetostrictive plate fixed at one end in a longitudinal direction and containing a magnetostrictive material, a coil housing at least part of the magnetostrictive plate, a magnetic-field generating portion disposed on the magnetostrictive plate and generating a magnetic field, a yoke containing a ferromagnetic material, and a magnetic-field adjusting portion containing a ferromagnetic material. The yoke is disposed outside the coil, and at least part of the yoke is fixed to the magnetostrictive plate. The magnetic-field adjusting portion is housed in part of the coil and is disposed in a vicinity of a surface of the magnetostrictive plate opposite to a surface to which the magnetic-field generating portion is fixed.

### BACKGROUND

### Field of the Disclosure

The present disclosure relates to power generating elements and power generating apparatuses including the power generating elements.

### Description of the Related Art

“Energy harvesting” technologies for obtaining electric power from unused energy present in environment have recently attracted attention as energy saving technologies. In particular, vibration-powered generation that obtains electric power from vibration provides a higher energy density than thermoelectric power generation that obtains electric power from heat, and therefore has been proposed for applications such as power sources for constant communication Internet of Things (IoT) and charging of mobile devices. For example, a magnet movable power generating method of vibrating a magnet by using vibration in the environment to generate induced electromotive force in a coil is applied in various forms. Furthermore, recent power generation proposed uses an inverse magnetostriction phenomenon in which magnetic flux density is changed by a change in force (hereinafter referred to as inverse magnetostrictive power generation), instead of vibration of a magnet.

Japanese Patent Laid-Open No. 2020-198692 discloses an inverse magnetostrictive power generating element configured such that a magnetostrictive portion and a magnetic portion (yoke) are connected magnetically in parallel. Japanese Patent Laid-Open No. 2021-136826 discloses an inverse magnetostrictive power generating element which includes at least two magnetic-field generating portions, in which one end of the magnetostrictive material is fixed, and in which a magnetic field generated from the magnetic-field generating portion close to the fixed end is larger than the magnetic field generated from the other magnetic-field generating portion.

However, the known methods may cause leakage flux outside the coil, for example, in the case where the power generating element is small, and cannot always extract the magnetic flux efficiently from the magnetic-field generating portion.

### SUMMARY

Aspects of the present disclosure provide a power generating element capable of efficient power generation using a magnetostrictive material and a power generating apparatus including the power generating element.

The present disclosure provides operational advantages that are obtained from the configurations of the following embodiments.

A power generating element according to an aspect of the present disclosure includes a magnetostrictive plate fixed at one end in a longitudinal direction and containing a magnetostrictive material, a coil housing at least part of the magnetostrictive plate, a magnetic-field generating portion disposed on the magnetostrictive plate and generating a magnetic field, a yoke containing a ferromagnetic material, and a magnetic-field adjusting portion containing a ferromagnetic material. The yoke is disposed outside the coil, and at least part of the yoke is fixed to the magnetostrictive plate. The magnetic-field adjusting portion is housed in part of the coil and is disposed in a vicinity of a surface of the magnetostrictive plate opposite to a surface to which the magnetic-field generating portion is fixed.

Further features of the present disclosure will become apparent from the following description of exemplary embodiments with reference to the attached drawings.

### BRIEF DESCRIPTION OF THE DRAWINGS

FIG. 1A is a schematic top view of a power generating element according to an embodiment illustrating the configuration thereof.

FIG. 1B is a schematic cross-sectional view of the power generating element.

FIG. 2A is a schematic cross-sectional view of a power generating element illustrating an example of the principle thereof.

FIG. 2B is a schematic cross-sectional view of the power generating element of this embodiment illustrating an example of the principle thereof.

FIGS. 3A to 3F are schematic diagrams illustrating and example of a method for manufacturing the power generating element according to the embodiment.

FIG. 4A is a schematic top view of a power generating element of Example 1 illustrating the configuration thereof.

FIG. 4B is a schematic cross-sectional view of the power generating element.

FIG. 5A is a schematic top view of a power generating element of Example 2 illustrating the configuration thereof.

FIG. 5B is a schematic cross-sectional view of the power generating element.

FIG. 6A is a schematic top view of a power generating element of Example 3 illustrating the configuration thereof.

FIG. 6B is a schematic cross-sectional view of the power generating element.

FIG. 7 is a schematic cross-sectional view of a power generating element of Example 4 illustrating the configuration thereof.

FIGS. 8A and 8B are schematic cross-sectional views of the power generating element of Example 4 illustrating an example of the principle thereof.

### DESCRIPTION OF THE EMBODIMENTS

Embodiments of the present disclosure will be described in detail below with reference to the accompanying drawings.

### First Embodiment

A power generating element according to a first embodiment generates electric power using an inverse magnetostriction phenomenon in which magnetic flux density is changed by a change in force instead of vibration of a magnet. The power generating element according to this embodiment improves the efficiency of power generation using a magnetic-field adjusting portion having the function of inducing leakage flux not contributing to power generation into a coil.

### Configuration of Power Generating Element

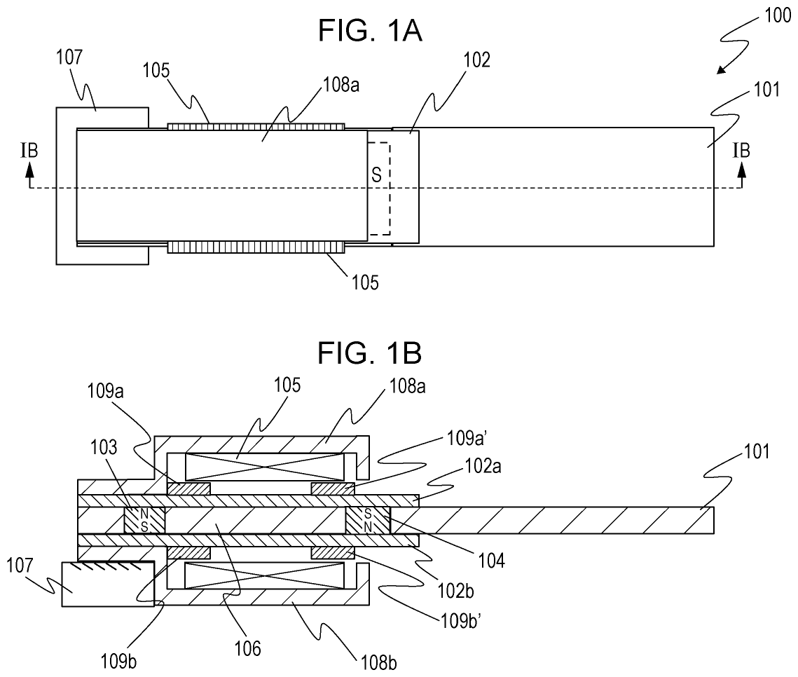

The configuration of the power generating element of this embodiment will be described with reference to FIGS. 1A and 1B. FIG. 1A is a schematic top view of the power generating element of this embodiment illustrating the configuration thereof. FIG. 1B is a schematic cross-sectional view of the power generating element of this embodiment taken along line IB-IB in FIG. 1A illustrating the configuration thereof.

The power generating element 100 of this embodiment is held by a holding portion 107 and includes a connecting plate 101, a magnetostrictive portion 102 including a magnetostrictive plate 102a and a magnetostrictive plate 102b, a magnetic-field generating portion including a magnet 104 in a first magnetic-field generation area and a magnet 103 in a second magnetic-field generation area, a coil 105, a nonmagnetic area 106, a magnetic portion 108 including a yoke 108a and a yoke 108b, and a magnetic-field adjusting portion 109 including a magnetic-field adjusting plate 109a and a magnetic-field adjusting plate 109b.

The connecting plate 101 is fixed to the magnetostrictive portion 102 at one end and is vibrated under external force, such as a compression stress and a tensile stress. The connecting plate 101 and the magnetostrictive portion 102 may be connected together using any method for firm fixation, for example, laser welding, bonding using an adhesive, solder joining, ultrasonic joining, or bolt-nut fixing. The connecting plate 101 may be made of a ductile material because the connecting plate 101 is subjected to continuous compression stress, tensile stress, and other external forces. The material for the connecting plate 101 is selected according to whether a magnetic circuit is constituted together with the magnetostrictive portion 102. For this reason, the connecting plate 101, if used as an element constituting a magnetic circuit, is made of a magnetic material, such as a carbon steel, a ferritic stainless steel (for example, SUS430), or a martensitic stainless steel (for example, SUS420J2). In contrast, if the connecting plate 101 is not used as an element constituting a magnetic circuit, a nonmagnetic material, such as an austenite stainless steel (for example, (SUS304, SUS303, or SUS316) is used.

The connecting plate 101 is subjected to a force so as to vibrate in the vertical direction in FIG. 1B. For this reason, the connecting plate 101 may be made of a spring material to reduce the mechanical damping of the vibration.

The force that induces the vibration in the vertical direction in FIG. 1B can be generated by ground excitation caused by the holding portion 107 fixed to a vibration source that vibrates in the vertical direction or an action such as applying a force to flick an end of the connecting plate 101 opposite to the connection. The methods for applying the forces are given for illustration and any other method for applying a force to the magnetostrictive portion 102 may be used in the disclosure.

The materials for the connecting plate 101 are given for illustration and are not intended to limit the disclosure.

The magnetostrictive plate 102a and the magnetostrictive plate 102b constituting the magnetostrictive portion 102 are fixed at one end in the longitudinal direction and contain a magnetostrictive material. The magnetostrictive portion 102 may contain a ductile magnetostrictive material because it is subjected to continuous compression stress and tensile stress. The magnetostrictive material may be an iron-gallium alloy, an iron-cobalt alloy, an iron-aluminum alloy, an iron-gallium-aluminum alloy, an iron-silicon-boron alloy, or any other kind of known magnetostrictive material. The magnetostrictive portion 102 may have any shape that is connectable to the connecting plate 101, such as a rectangular parallelepiped or a column. The yokes 108a and 108b may be any members that contain a ferromagnetic material and are magnetically connected to the magnetostrictive materials 102a and 102b, respectively, for example, a carbon steel, a ferritic stainless steel (for example, SUS430) or a martensitic stainless steel (for example, SUS420J2). The magnetostrictive portion 102 and the magnetic portion 108 are joined together. The magnetostrictive portion 102 and the magnetic portion 108 may be connected to together using any method for firm fixation, for example, laser welding, bonding using an adhesive, solder joining, ultrasonic joining, or bolt-nut fixing.

The magnet 103 of the first magnetic-field generation area and the magnet 104 of the second magnetic-field generation area that constitute the magnetic-field generating portion are mounted to magnetize the magnetostrictive plate 102a and the magnetostrictive plate 102b in reverse directions. Examples of the magnet 103 and the magnet 104 include, but are not limited to, a neodymium magnet and a samarium-cobalt magnet.

An example of the directions of the magnetic poles of the magnets 103 and 104 is, but not limited to, vertically reverse as shown in the schematic cross-sectional view of FIG. 1B. The directions of the magnetic poles of the magnets 103 and 104 in the schematic cross-sectional view of FIG. 1B are given for mere illustration and may be reverse in N-pole and S-pole from those shown in the drawing. In other words, the magnet 103 and the magnet 104 need only be fixed at different magnetic poles to the magnetostrictive portion 102.

The arrangement of the first magnetic-field generation area and the second magnetic-field generation area is not limited to the above. They may be arranged in any way in which the magnetostrictive plate 102a and the magnetostrictive plate 102b are magnetized in reverse directions. Examples of the magnets 103 and 104 include, but are not limited to, a neodymium magnet and a samarium-cobalt magnet.

The coil 105 is disposed so as to house at least part of each of the magnetostrictive plate 102a and the magnetostrictive plate 102b and generates a voltage in response to temporal changes in the magnetic flux generated in the magnetostrictive plate 102a and the magnetostrictive plate 102b according to Faraday's law of electromagnetic induction. This allows the number of coil turns to be increased irrespective of the distance between the two magnetostrictive plates 102a and 102b.

An example of a material for the coil 105 is, but not limited to, a copper wire.

Examples of a material for the nonmagnetic area 106 include, but are not limited to, gas and a solid. For example, air, ductile nonmagnetic metal, or an austenite stainless steel (for example, SUS304, SUS303, or SUS316) is used. The nonmagnetic area 106 may be integral to the connecting plate 101.

Housing the power generating element 100 in a container integral to the holding portion 107 reduces the risk of damage to the power generating element 100 and the risk of contact with another member that interferes with vibration. Examples of a material for the container include, but are not limited to, a carbon steel, a ferritic stainless steel (for example, SUS430), and a martensitic stainless steel (for example, SUS420J2), which are magnetic materials. The use of the materials provides the effect of magnetic shield, thereby reducing the influence of external magnetism.

The magnetic-field adjusting portion 109 should contain a ferromagnetic material and may be disposed in any position housed in part of the coil 105 and in a vicinity of a surface of the magnetostrictive portion 102 opposite to a surface on which the magnetic-field generating portion is disposed. For example, the magnetic-field adjusting portion 109 may be disposed between the yoke 108 and the magnetostrictive portion 102, as shown in FIG. 1B. Examples of a material for the magnetic-field adjusting portion 109 include a carbon steel, a ferritic stainless steel (for example, SUS430), a martensitic stainless steel (for example, SUS420J2), and other magnetostrictive materials. The magnetic-field adjusting portion 109 may be join to the magnetostrictive portion 102 and the yoke 108 using any method for firm fixation, for example, laser welding, bonding using an adhesive, solder joining, ultrasonic joining, or bolt-nut fixing.

In other words, the power generating element 100 disclosed in the present disclosure includes the magnetostrictive portion 102 fixed at one end in the longitudinal direction and containing a magnetostrictive material, the coil 105 housing at least part of the magnetostrictive portion 102, and the magnetic-field generating portions (magnets) 103 and 104 disposed on the magnetostrictive portion 102 and generating a magnetic field. The power generating element 100 is configured to generate electric power by applying a force to the magnetostrictive portion 102. The power generating element 100 further includes the yoke 108 containing a ferromagnetic material and the magnetic-field adjusting portion 109 containing a ferromagnetic material. The yoke 108 is disposed outside the coil 105, and at least part of the yoke 108 is fixed to the magnetostrictive portion 102. The magnetic-field adjusting portion 109 is housed in part of the coil 105 and is disposed in a vicinity of a surface of the magnetostrictive portion 102 opposite to a surface to which the magnetic-field generating portions 103 and 104 are fixed.

### Operation

The power generating element 100 of this embodiment is a kind of electromagnetic induction power generating element that converts a change in magnetic flux to a voltage using a coil. The electromagnetic induction produces an electromotive force V according to Eq. 1.

V=N×Δϕ/Δt Eq. 1

where N is the number of turns of the coil 105, and Δϕ is the amount of change in magnetic flux in the coil 105 during time Δt. In power generation based on the inverse magnetostriction phenomenon, Δϕ is caused by a change in a magnetic field H-magnetic flux density B curve (hereinafter referred to as B-H curve) due to a change in stress applied to the magnetostrictive material. The value Δϕ is very small in the case where the applied magnetic field H is excessively large or small. For this reason, an appropriate magnetic field needs to be applied to the magnetostrictive material. However, if the entire power generating element is small, the distance between the structure constituting the power generating element and the magnetostrictive plate is small, which may cause leakage flux to produce a magnetic field distribution in the magnetostrictive plate. Furthermore, if the magnetostrictive plate close to the magnetic-field generating portion reaches a saturated magnetic flux density, leakage flux may be generated. Accordingly, this embodiment discloses the power generating element 100 that is increased in power generation efficiency by compensating the leakage flux of the magnetostrictive plate which can be caused ty the small distance between the structures while preventing the magnetostrictive plate from reaching a saturated magnetic flux density.

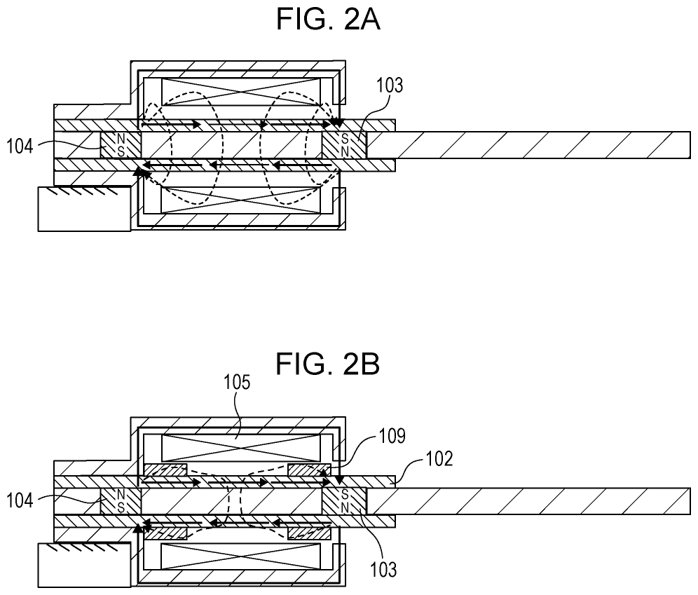

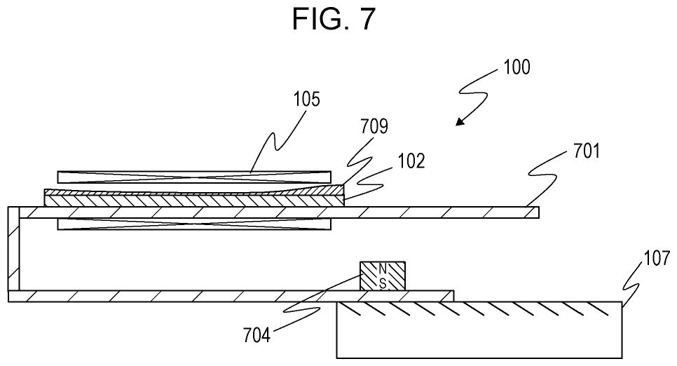

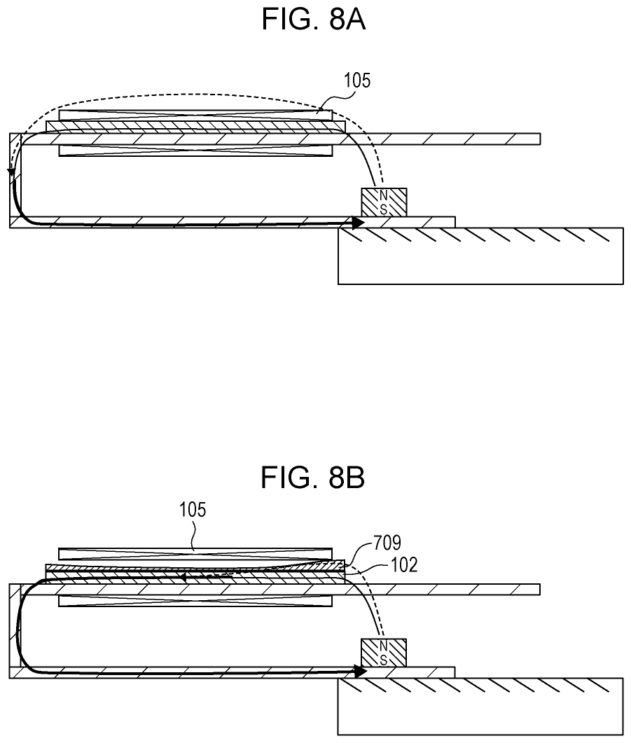

FIG. 2A is a schematic cross-sectional view of a power generating element that generates electric power using an inverse magnetostriction phenomenon illustrating the degree of the density and the direction of magnetic flux passing through the magnetostrictive plates using the arrows and their thicknesses. FIG. 2B is a schematic cross-sectional view of the power generating element 100 of an example of this embodiment shown in FIGS. 1A and 1B illustrating the degree of the density and the direction of magnetic flux using the arrows and their thicknesses. In FIG. 2A, the magnetic flux leaks outside the magnetostrictive plates in the vicinity of the magnets 103 and 104. The dotted lines schematically indicate the magnetic flux that leaks out of the magnetostrictive plates. Much of the leakage flux does not pass through the coil in the direction perpendicular to the cross section of the coil. This leakage flux does not contribute to power generation and thus reduces the efficiency of power generation. Furthermore, around the center of the magnetostrictive plates in the longitudinal direction in FIG. 2B, leakage flux is generated in the opposing magnetostrictive plates, which decreases the magnetic flux density, resulting in a decrease in the efficiency of power generation. Our diligent study showed that disposing the ferromagnetic magnetic-field adjusting portion 109 inside part of the coil 105 and in a vicinity of a surface of the magnetostrictive portion 102 opposite to the surface on which the magnets 103 and 104 are disposed, as in this embodiment shown in FIG. 2B, allows the leakage flux due to the saturated magnetic flux density of the magnetostrictive portion 102 in the vicinity of the magnets 103 and 104 to be used as magnetic flux compensating for the leakage flux generated around the center of the magnetostrictive portion 102 in the longitudinal direction, thereby improving the efficiency of power generation. In other words, the magnetic-field adjusting portion 109 is in a vicinity of the magnetostrictive portion 102 and increases in magnetic resistance with increasing distance from the closest magnet. The increase in magnetic resistance with distance means that the magnetic permeability of the component decreases, or the cross-sectional area decreases with distance. For example, since the magnetic-field adjusting portion 109 is housed only in part of the coil 105, as in FIG. 2B, the magnetic-field adjusting portion 109 with high magnetic permeability and the air area with low magnetic permeability are housed in the coil 105, and thus the magnetic resistance increases with distance. In FIG. 2B, the magnetic-field adjusting portion 109 is in contact with both the yoke 108 and the magnetostrictive portion 102. Alternatively, even if the magnetic-field adjusting portion 109 is in contact with one of the yoke 108 and the magnetostrictive portion 102, as in FIGS. 7, 8A and 8B, the efficiency of power generation can be improved. The magnetic-field adjusting portion 109 may be in non-contact with the yoke 108 and the magnetostrictive portion 102.

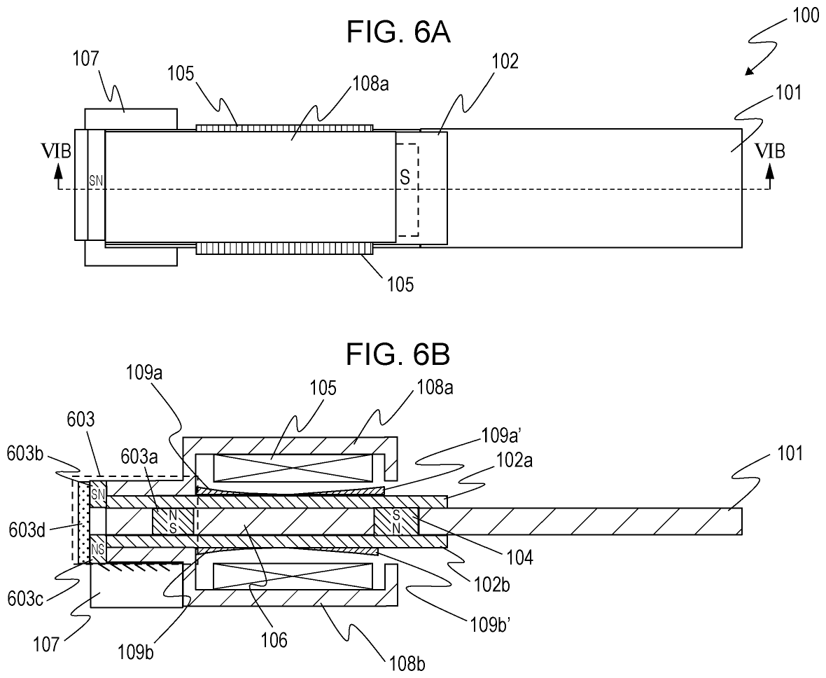

The study also showed that varying the thickness of the magnetic-field adjusting portion 109 according to the leakage flux from the magnetostrictive portion 102 as shown in FIG. 6B increases the magnetic resistance with the distance, improving the efficiency of power generation. In other words, decreasing the thickness of the ferromagnetic material contained in the magnetic-field adjusting portion 109 with increasing distance from the closest magnet in the longitudinal direction decreases the magnetic resistance of the magnetic-field adjusting portion 109 in the vicinity of the magnet where much leakage flux is generated and increases the magnetic resistance of an area distant from the magnet where little leakage flux is generated, which allows the magnetic flux to be efficiently used by the magnetostrictive portion 102, improving the efficiency of power generation. The proportion of the ferromagnetic material contained in the magnetic-field adjusting portion 109 may be decreased with the distance from the closest magnet.

Unlike FIGS. 2A and 2B, even with a single magnetostrictive portion 102, as in FIG. 7, disposing a magnetic-field adjusting portion 709 on a surface of the magnetostrictive portion 102 opposite to the surface on which a magnet 704 is disposed allows the leakage flux to be efficiently used, improving the efficiency of power generation.

Specifically, as shown in FIG. 8A in which the magnetic-field adjusting portion 709 is not provided, the leakage flux that does not pass through a coil 105, indicated by the dotted line, is generated to decrease the efficiency of power generation. In contrast, as in this embodiment of FIG. 8B, disposing the magnetic-field adjusting portion 709 in a vicinity of the surface of the magnetostrictive portion 102 opposite to the surface to which magnetic flux flows guides the leakage flux to the magnetostrictive plate to be efficiently used, thereby improving the efficiency of power generation. In other words, the power generating element includes a magnetostrictive portion 102 containing a magnetostrictive material, a yoke containing a ferromagnetic material, the magnetic-field adjusting portion 709 containing a ferromagnetic material, the coil 105 that houses at least part of the magnetostrictive portion 102 and the yoke, and a magnetic-field generating portion fixed to part of the yoke and generating a magnetic field. The magnetostrictive portion 102 is fixed to the yoke. The yoke is fixed at one end to a holding portion. The magnetic-field adjusting portion 709 is housed in part of the coil 105 and is disposed in a vicinity of a surface of the magnetostrictive portion 102 opposite to a surface into which magnetic flux flows.

### EXAMPLES

The present disclosure will be described in detail below with reference to specific examples. It is to be understood that the present disclosure is not limited to the configurations and forms of the examples.

### Example 1

### Method for Manufacturing Power Generating Element

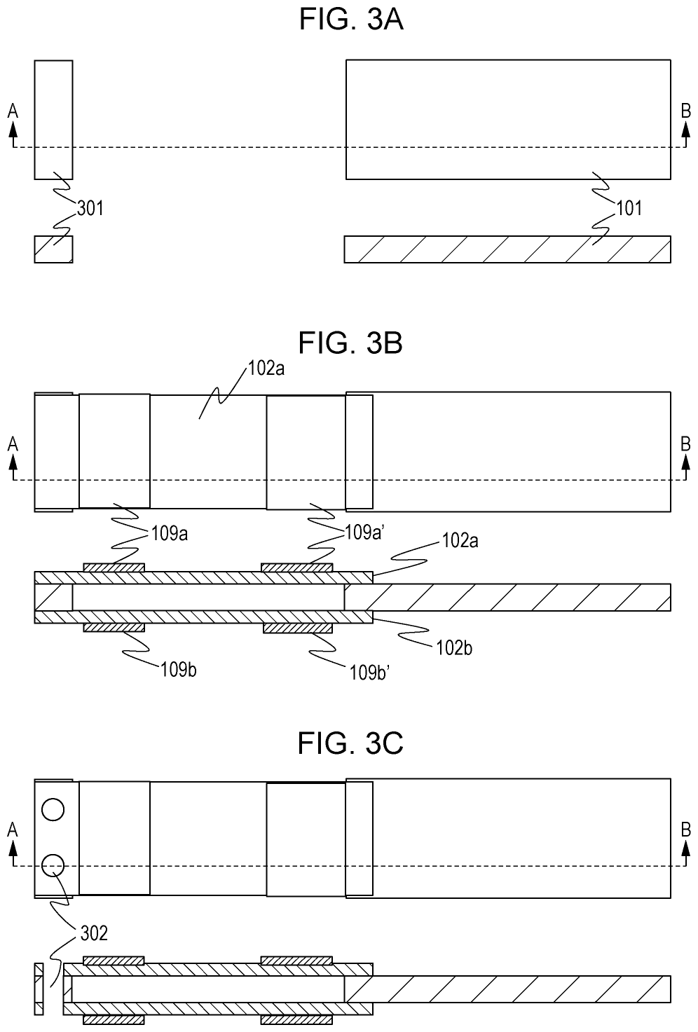

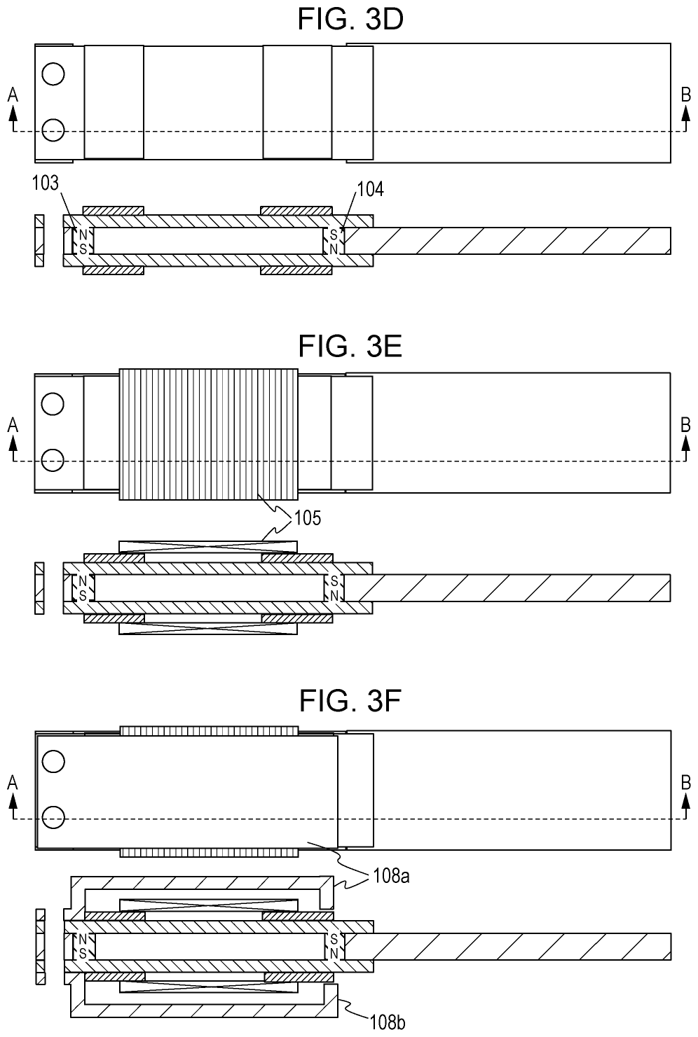

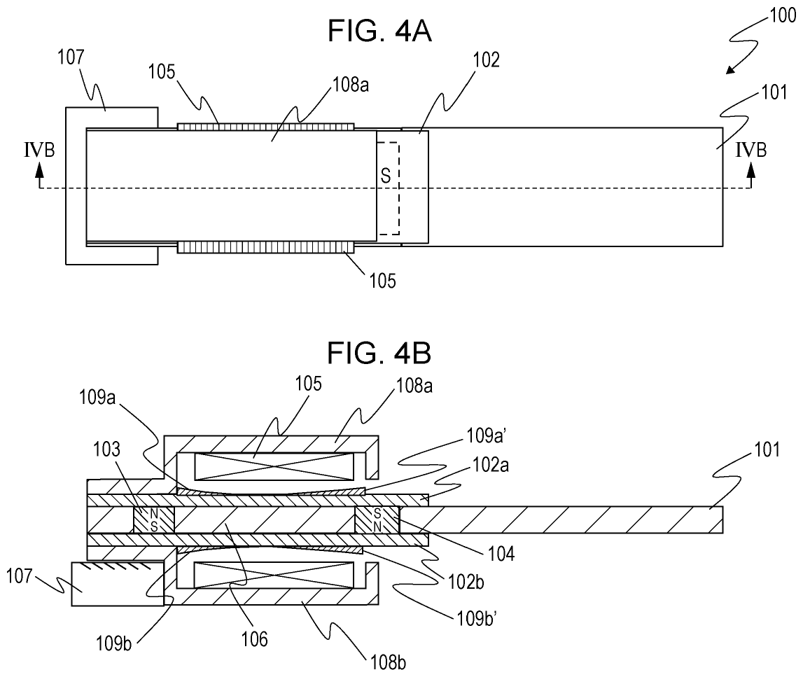

In this example, the power generating element 100 illustrated in FIGS. 4A and 4B was fabricated. An example of the individual manufacturing processes will be described with reference to FIGS. 3A to 3F.

The upper drawings in FIGS. 3A to 3F are schematic top views, and the lower drawings are respective schematic cross-sectional views taken along line A-B in the schematic top views.

First, the connecting plate 101 made of a spring austenite stainless steel SUS304-CSP 1.0 mm thick, 16 mm wide, and 35 mm long was prepared. A holding plate 301 made of SUS304 1.0 mm thick, 16 mm wide, and 5 mm long was prepared. The austenite stainless steel, which is nonmagnetic metal, was used to reduce the leakage of magnetic flux between the magnetostrictive plate 102a and the magnetostrictive plate 102b. The reason why the spring material was used is that the study showed that the mechanical damping of the power generating element related to power generation performance is smaller than that using a normal stainless material [FIG. 3A].

Next, the magnetostrictive plates 102a and 102b to which magnetic-field adjusting plates 109a, 109a′, 109b, and 109b′ constituting the magnetic-field adjusting portion 109 are bonded were bonded to the connecting plate 101 and the holding plate 301 with an epoxy adhesive. Thereafter, the ridges of the magnetostrictive plates 102a and 102b in contact with the connecting plate 101 and the holding plate 301 were bonded using laser welding.

The magnetic-field adjusting plates 109a, 109a′, 109b, and 109b′ used were cold rolled steel plates SPCC 0.15 mm thick, 15 mm wide and 5 mm long, and the magnetostrictive plates 102a and 102b used were iron-gallium alloys 0.5 mm thick, 15 mm wide, and 25 mm long. The magnetic-field adjusting plates 109a, 109a′, 109b, and 109b′ and the magnetostrictive plates 102a and 102b were bonded together with an epoxy adhesive, and then the ridges of the magnetic-field adjusting plates 109a, 109a′, 109b, and 109b′ were bonded using laser welding. For magnetic field adjustment to the magnetic field environment in a vicinity of the magnetic-field generating portions, the magnetic-field adjusting plates 109a′ and 109b′ were processed so as to become thin on the left side in the drawings, and the magnetic-field adjusting plates 109a and 109b were processed so as to become thin on the right side in the drawings. However, the yokes 108a and 108b, which have low magnetic resistance, were provided around the magnetic-field adjusting plates 109a and 109b, so that no leakage flux are generated. For this reason, the magnetic-field adjusting plates 109a and 109b were not practically provided, and only the magnetic-field adjusting plates 109a′ and 109b′ were provided. FIG. 3B illustrates all of the magnetic-field adjusting plates 109a, 109b, 109a′, and 109b′ as a general form of this embodiment [FIG. 3B].

Next, holding screw holes 302 for fixing the power generating element with bolts or the like were formed in the magnetostrictive plates 102a and 102b and the connecting plate 101. The screw holes 302 enable the power generating element to be installed in various sites. In evaluating the amount of power generated in the embodiment, a spacer including screw holes was placed on an optical bench, and the holding screw holes 302 were fitted in the spacer and were fixed together with bolts [FIG. 3C].

The neodymium magnet 103 1.0 mm thick, 12 mm wide, and 2.0 mm long was prepared. The neodymium magnet 104 1.0 mm thick, 12 mm wide, and 1.0 mm long was prepared. The magnet 103 and the magnet 104 are inserted so that the magnetic poles are opposite and are then bonded between the magnetostrictive plate 102a and the magnetostrictive plate 102b with an epoxy adhesive, as shown in FIG. 3D [FIG. 3D].

Next, the coil 105, which is a 2,000-turn air core coil made of a copper wire with a diameter of 0.1 mm, was inserted into the area between the magnet 103 and the magnet 104 so as to house the magnetostrictive plate 102a and the magnetostrictive plate 102b and was fixed with electrically insulating varnish [FIG. 3E].

Lastly, the yokes 108a and 108b (magnetic portion), which are made of cold rolled steel plates SPCC 1.5 mm thick, 15 mm wide, and 25 mm long, for adjusting a change in magnetic flux, were fitted and fixed through the screw holes 302 [FIG. 3F].

### Evaluating Power Generating Element

The power generation performance of the power generating element 100 fabricated as described above was evaluated by vibrating the holding portion 107 with a vibrator and measuring the open-circuit voltage generated in the coil 105 with an oscilloscope. The frequency to be generated by the vibrator was set at 100 Hz, and the vibration acceleration was set at 1 G. A weight with a natural frequency of 100 Hz was disposed at an end of the power generating element 100. The amount of generated power P calculated from the voltage waveform measured with an oscilloscope using Eq. 2 was used as a quantitative index for the power generation performance.

P=Σ(V(t))²/(4×R)×Δt/t Eq. 2

where V(t) is an open-circuit voltage measured with an oscilloscope during time t, R is the electrical resistance of the coil 105, Δt is the temporal resolution of the oscilloscope, and Σ is summation for time t. Eq. 2 for the amount of generated power P excludes the effect of inductance of the coil 105. This is because the examples and the comparative examples use coils with the same size, allowing for relative comparison. The result of measurement and evaluation using the above method showed that the electrical resistance of the coil 105 was 180Ω, the maximum value of the open-circuit voltage was 8.4 V, and the amount of generated power P calculated using Eq. 2 was 22 mW.

### Example 2

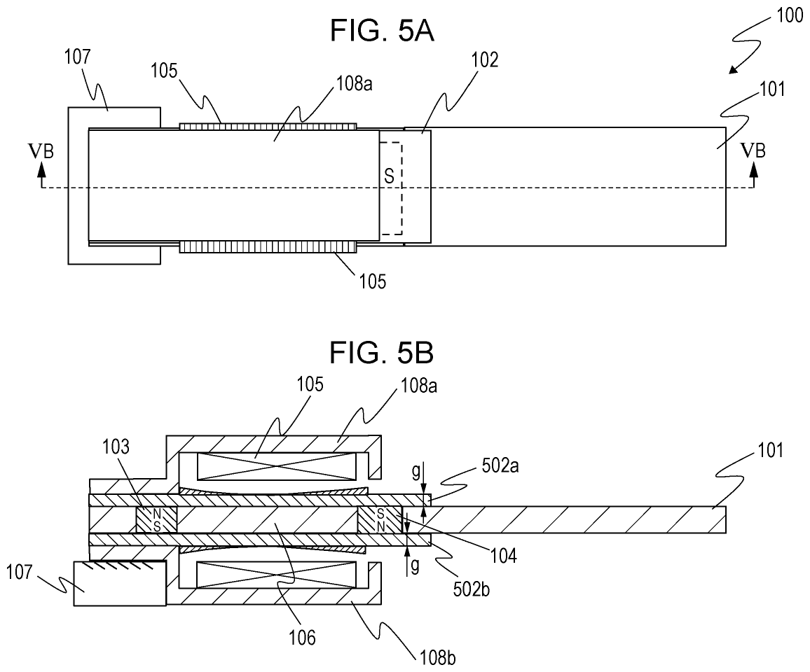

In this example, the power generating element 100 illustrated in FIGS. 5A and 5B was fabricated. This example showed that varying the thickness of magnetostrictive plates 502a and 502b provides a magnetic-field adjusting function, thereby increasing the amount of power generated. In other words, the power generating element 100 of this example includes a magnetostrictive plate 502 fixed at one end in the longitudinal direction and containing a magnetostrictive material, a coil 105 housing at least part of the magnetostrictive plate 502, and magnetic-field generating portions (magnets) 103 and 104 disposed on the magnetostrictive plate 502 and generating a magnetic field. The power generating element 100 is configured to generate electric power by applying a force to the magnetostrictive plate 502. The power generating element 100 further includes a yoke 108 containing a ferromagnetic material. The yoke 108 is disposed outside the coil 105, and at least part of the yoke 108 is fixed to the magnetostrictive plate 502. The magnetostrictive plate 502 increases in magnetic resistance with increasing distance from a closest magnet. The thicknesses g of the magnetostrictive plates 502a and 502b of the power generating element 100 decrease with increasing distance from the closest magnet in the longitudinal direction.

The method of manufacture is the same as that of Example 1. In Example 1, the magnetic-field adjusting portion 109 and the magnetostrictive portion 102 are made of different materials. In Example 2, the magnetostrictive plates 502a and 502b have a thickness of 1.2 mm, and the portions other than the vicinity of the magnets 103 and 104 were file to 1.5 mm in thickness, and the vicinity of the magnets 103 and 104 was filed to 1.6 mm in thickness, thereby providing the magnetostrictive plates 502a and 502b with the magnetic-field adjusting function.

### Evaluating Power Generating Element

The power generation performance of the power generating element 100 fabricated as described above was evaluated as in Example 1. The result of evaluation showed that the electrical resistance of the coil 105 was 180Ω, the maximum value of the open-circuit voltage was 7.8 V, and the amount of generated power P was 19 mW.

### Example 3

In this example, the power generating element 100 illustrated in FIGS. 6A and 6B was fabricated. The method of manufacture is the same as that of Example 1. However, a process for forming a magnetic-field generating portion 603 with a plurality of magnets is added at the last process. The magnetic-field generating portion 603 was constituted by a plurality of spatially separated magnets 603a, 603b, and 603c. The magnets 603b and 603c are arranged so that their magnetic poles are reverse in the longitudinal direction of the magnetostrictive plates 102a and 102b, and the magnets 603a, 603b, and 603c are arranged in positional relationship in which their magnetic poles cause reverse magnetic fields in the magnetostrictive plates 102a and 102b, thereby inducing much more magnetic flux in the magnetostrictive plates 102a and 102b. This may increase the generated power. Specifically, neodymium magnets were used as the magnets 603b and 603c, and a cold rolled steel plate SPCC with a thickness of 1 mm was used as a magnetic plate 603d for reducing the leakage flux between the magnets 603b and 603c, which are bonded together with an epoxy adhesive.

Unlike Example 1, the configuration of the magnetic-field generating portion 603 constituted by a plurality of magnets with reverse poles causes more leakage flux in a vicinity of the magnet 603a than in a vicinity of the magnet 104.

For this reason, the thicknesses of the magnetic-field adjusting plates 109a and 109b of Example 3 were larger than those of the magnetic-field adjusting plates 109a′ and 109b′. Specifically, the maximum thicknesses of the magnetic-field adjusting plates 109a and 109b were set at 0.3 mm, and the maximum thicknesses of the magnetic-field adjusting plates 109a′ and 109b′ were set at 0.15 mm.

### Evaluating Power Generating Element

The power generation performance of the power generating element 100 fabricated as described above was evaluated as in Example 1. The result of evaluation showed that the electrical resistance of the coil 105 was 180Ω, the maximum value of the open-circuit voltage was 10 V, and the amount of generated power P was 30 mW.

### Example 4

In this example, the power generating element 100 illustrated in FIG. 7 was fabricated. A connecting plate 701 integral to a yoke was made of SUS420J2 with a thickness of 1.0 mm into U-shape. A magnetic-field adjusting plate 709 was filed to have a maximum thickness of about 0.15 mm. A neodymium magnet 704 3 mm thick, 7 mm wide, and 7 mm long was used. The magnet 704 and the connecting plate 701 were bonded together with an epoxy resin. In other words, the power generating element 100 includes a magnetostrictive portion 102 fixed at one end in the longitudinal direction and containing a magnetostrictive material, the yoke (connecting plate) 701 containing a ferromagnetic material, a coil 105 housing at least part of the magnetostrictive material, and a magnetic-field generating portion (magnet) 704 fixed to the yoke 701 and generating a magnetic field. Part of the yoke 701 is disposed outside the coil 105, and at least part of the surface of the yoke 701 is fixed to the magnetostrictive portion 102. Another part of the yoke 701 is housed in part of the coil 105 and is disposed in a vicinity of a surface of the magnetostrictive portion 102 opposite to a surface to which the magnetic-field generating portion 704 is fixed.

### Evaluating Power Generating Element

The power generation performance of the power generating element 100 fabricated as described above was evaluated as in Example 1. The result of evaluation showed that the electrical resistance of the coil 105 was 180Ω, the maximum value of the open-circuit voltage was 4 V, and the amount of generated power P was 5 mJ.

### Comparative Example 1

In this comparative example, a power generating element without the magnetic-field adjusting plates 109a, 109b, 109a′, and 109b′ was fabricated, unlike the power generating element 100 of Example 1 in FIGS. 4A and 4B. The configuration other than that having no magnetic-field adjusting plate is the same, including the size, as the configuration in FIGS. 4A and 4B. The power generating element was fabricated by using the magnetostrictive plates 102a and 102b without the magnetic-field adjusting plates 109a, 109b, 109a′, and 109b′ in FIG. 3B.

### Evaluating Power Generating Element

The power generation performance of the power generating element fabricated as described above was evaluated as in Example 1. The result of evaluation showed that the electrical resistance of the coil was 180Ω, the maximum value of the open-circuit voltage was 6.5 V, and the amount of generated power P was 13 mJ.

### Comparative Example 2

In this comparative example, a power generating element without the magnetic-field adjusting plates 109a, 109b, 109a′, and 109b′ was fabricated, unlike the power generating element 100 of Example 3 in FIGS. 6A and 6B. The configuration other than that having no magnetic-field adjusting plate is the same, including the size, as the configuration in FIGS. 6A and 6B. The power generating element was fabricated by using the magnetostrictive plates 102a and 102b without the magnetic-field adjusting plates 109a, 109b, 109a′, and 109b′ in the manufacturing process of Example 3.

### Evaluating Power Generating Element

The power generation performance of the power generating element fabricated as described above was evaluated as in Example 1. The result of evaluation showed that the electrical resistance of the coil was 180Ω, the maximum value of the open-circuit voltage was 7 V, and the amount of generated power P was 15 mJ.

### Comparative Example 3

In this comparative example, a power generating element without the magnetic-field adjusting portion 709 was fabricated, unlike the power generating element 100 of Example 4 in FIG. 7.

### Evaluating Power Generating Element

The power generation performance of the power generating element fabricated as described above was evaluated as in Example 1. The result of evaluation showed that the electrical resistance of the coil was 180Ω, the maximum value of the open-circuit voltage was 3 V, and the amount of generated power P was 3 mJ.

The power generating elements according to the embodiments and examples generate more power than known inverse magnetostrictive power generating elements, which allows for providing compact power generators (power generating apparatuses). They are effective particularly as power generators for apparatuses of a size difficult to install, for example, power generators (power generating apparatuses) for mobile devices. Furthermore, installing the power generators in the casings of power generating apparatuses having the mechanism for vibrating the power generating element underground excitation (the mechanism for applying force to the power generating element), for example, industrial equipment, business equipment, or medical equipment that generate vibrations, or automobiles, rail vehicles, aircrafts, heavy machines, or marine vessels may allow the power generators to be used as power sources for various types of equipment including Internet-of-Things (IoT) equipment. The casings may be ferromagnetic bodies. The present disclosure enhances the performance of power generators. This allows for application to a wide range of fields other than those described above.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of priority from Japanese Patent Application No. 2022-010274, filed Jan. 26, 2022, which is hereby incorporated by reference herein in its entirety.

What is claimed is:

1. A power generating element comprising:
a magnetostrictive plate fixed at one end in a longitudinal direction and containing a magnetostrictive material;
a coil housing at least part of the magnetostrictive plate;
a magnetic-field generating portion disposed on the magnetostrictive plate and generating a magnetic field;
a yoke containing a ferromagnetic material; and
a magnetic-field adjusting portion containing a ferromagnetic material,
wherein the yoke is disposed outside the coil, and at least part of the yoke is fixed to the magnetostrictive plate, and
wherein the magnetic-field adjusting portion is housed in part of the coil and is disposed in a vicinity of a surface of the magnetostrictive plate opposite to a surface to which the magnetic-field generating portion is fixed.

2. The power generating element according to claim 1, wherein the magnetic-field adjusting portion is disposed between the yoke and the magnetostrictive plate.

3. The power generating element according to claim 1, wherein the magnetic-field adjusting portion is fixed to the magnetostrictive plate.

4. The power generating element according to claim 1, wherein the magnetic-field adjusting portion is fixed to the yoke.

5. The power generating element according to claim 1, wherein the magnetic-field adjusting portion is not in contact with the yoke and the magnetostrictive plate.

6. The power generating element according to claim 1, wherein the magnetic-field adjusting portion is disposed in a vicinity of the magnetostrictive plate and increases in magnetic resistance with increasing distance from a closest magnet.

7. The power generating element according to claim 6, wherein the ferromagnetic material contained in the magnetic-field adjusting portion decreases in thickness with increasing distance from the closest magnet in the longitudinal direction.

8. The power generating element according to claim 6, wherein the ferromagnetic material contained in the magnetic-field adjusting portion decreases in proportion with increasing distance from the closest magnet in the longitudinal direction.

9. A power generating element comprising:
a magnetostrictive plate fixed at one end in a longitudinal direction and containing a magnetostrictive material;
a coil housing at least part of the magnetostrictive plate;
a magnetic-field generating portion disposed on the magnetostrictive plate and generating a magnetic field; and
a yoke containing a ferromagnetic material,
wherein part of the yoke is disposed outside the coil, and at least part of the yoke is fixed to the magnetostrictive plate, and
wherein another part of the yoke is housed in part of the coil and is disposed in a vicinity of a surface of the magnetostrictive plate opposite to a surface to which the magnetic-field generating portion is fixed.

10. A power generating element comprising:
a magnetostrictive plate fixed at one end in a longitudinal direction and containing a magnetostrictive material;
a coil housing at least part of the magnetostrictive plate;
a magnetic-field generating portion disposed on the magnetostrictive plate and generating a magnetic field; and
a yoke containing a ferromagnetic material; and
wherein the yoke is disposed outside the coil, and at least part of the yoke is fixed to the magnetostrictive plate, and
wherein the magnetostrictive plate increases in magnetic resistance with increasing distance from a closest magnet.

11. The power generating element according to claim 10, wherein the magnetostrictive plate decreases in thickness with increasing distance from the closest magnet.

12. The power generating element according to claim 10, wherein the magnetostrictive material contained in the magnetostrictive plate decreases in proportion with increasing distance from the closest magnet.

13. A power generating element comprising:
a magnetostrictive plate containing a magnetostrictive material;
a yoke containing a ferromagnetic material;
a magnetic-field adjusting portion containing a ferromagnetic material;
a coil housing at least part of the magnetostrictive plate and the yoke; and
a magnetic-field generating portion fixed to part of the yoke and generating a magnetic field,
wherein the magnetostrictive plate is fixed to the yoke,
wherein the yoke is fixed at one end, and
wherein the magnetic-field adjusting portion is housed in part of the coil and is disposed in a vicinity of a surface of the magnetostrictive plate opposite to a surface to which magnetic flux flows.

14. The power generating element according to claim 1, further comprising:
a holding plate that vibrates under external force,
wherein the holding plate is fixed at one end to the magnetostrictive plate.

15. A power generating apparatus comprising:
the power generating element according to claim 1; and
a mechanism for applying force to the power generating element.

16. A power generating apparatus comprising:
the power generating element according to claim 1; and
a mechanism configured to cause the power generation element to vibrate due to a ground vibration.

17. A power generating apparatus comprising:
the power generating element according to claim 1; and
a casing housing the power generating element.

18. The power generating apparatus according to claim 17, wherein the casing comprises a ferromagnetic body.
